(19) United States
(12) Patent Application Publication
(10) Pub. No.: US 2026/0143611 A1
(43) Pub. Date: May 21, 2026

(54) SNAP-FIT INSERT

(71) Applicant: Hubbell Incorporated, Shelton, CT (US)

(72) Inventor: Paul Alfaro, Jr., Orange, CA (US)

(21) Appl. No.: 19/372,733

(22) Filed: Oct. 29, 2025

Related U.S. Application Data
(60) Provisional application No. 63/713,326, filed on Oct. 29, 2024.
(60) Provisional application No. 63/773,535, filed on Mar. 18, 2025.

(51) Int. Cl. H05K 5/15; H05K 5/02

(52) U.S. Cl. CPC H05K 5/15; H05K 5/0217

(57) ABSTRACT

An enclosure for selectively enclosing an electrical device. The enclosure includes an enclosure body that includes a first half with a first opening and a second half with a second opening. The second half is movable relative to the first half between an opened position and a closed position. The enclosure further includes a first connection feature removably connected to the first half through the first opening and a second connection feature removably connected to the second half through the second opening. The first connection feature and the second connection feature can selectively engage with a snap-fit connection when the first half and the second half are in the closed position. The enclosure body is constructed via a first manufacturing process and wherein the first connection feature and the second connection feature are constructed via a second manufacturing process.

### CROSS-REFERENCE TO RELATED APPLICATION:

This application claims the benefit of U.S. Provisional Application No. 63/773,535, filed Mar. 18, 2025, and U.S. Provisional Application No. 63/713,326, filed Oct. 29, 2024, the entire contents of these applications are incorporated herein by reference in their entirety.

### FIELD

The present disclosure relates to a pair of connection inserts. More particularly, the present disclosure relates to a pair of snap-fit connection inserts for use with injection molded parts.

### BACKGROUND

In manufacturing, a selected manufacturing method may influence the structure of the resulting component. Components formed with simpler methods may include simpler features or subcomponents. For example, simpler or cheaper manufacturing methods may be unable to create elements with more complex features or subcomponents. Additionally, some manufacturing methods may require the use of parts that are expensive or not reusable. For example, a thermoforming process may require the use of push fasteners which have only a single use. In other examples, a mold or other element may be specific to a single component and multiple parts may be needed to manufacture a variety of different parts. Utilizing standard or universal components in the manufacturing process may assist in improving the efficiency of the process.

### SUMMARY

Various embodiments of the present disclosure can overcome various of the aforementioned and other disadvantages associated with known injection mold inserts and offer new advantages as well.

According to one aspect of various embodiments of the present disclosure there is provided a male connector for forming a snap-fit connection. The male connector includes a first base and a male insert. The male insert includes a body and a pair of tabs. The body has a first end connected to the first base and a second end spaced apart from the first base. A first axis intersects the first end and a first portion of the body and a second axis intersects the second end and a second portion of the body. The first axis is not parallel to the second axis. A pair of tabs are disposed between the first end and the second end. The tabs project away from the body in a direction substantially perpendicular to the second axis.

In some forms, a) the first base and the male insert are each constructed using injection molding and are removably connected to one another with a snap-fit engagement; b) the body further includes a retaining feature disposed on an outer surface of the body proximate to the first end; c) the retaining feature includes a first wall protruding from the body, a second wall protruding from the body, and a groove formed between the first wall and the second wall; and/or d) the body further includes a prong disposed on an inner surface of the body proximate to the first end.

According to one aspect of various embodiments of the present disclosure there is provided a female connector for forming a snap-fit connection. The female connector includes a second base and a female insert. The female insert includes a body and an aperture. The body includes a first end connected to the first base and a second end spaced apart from the first base. A first axis extends between the first end and the second end. The aperture is disposed at the second end configured to receive a male connector.

In some forms, a) the body further includes a retaining feature disposed on an outer surface of the body proximate to the first end; b) the retaining feature includes a first wall protruding from the body, a second wall protruding from the body, and a groove formed between the first wall and the second wall; and/or c) the body further includes a prong disposed on an inner surface of the body proximate to the first end.

In some forms, a) the second base and the female insert are integrally formed; b) the second base further includes a pair of tabs projecting in a direction perpendicular to the first axis; and/or c) the pair of tabs can be received through an opening for form a snap-fit engagement.

According to one aspect of various embodiments of the present disclosure there is provided an enclosure for selectively enclosing an electrical device. The enclosure includes an enclosure body that includes a first half with a first opening and a second half with a second opening. The second half is movable relative to the first half between an opened position and a closed position. The enclosure further includes a first connection feature removably connected to the first half through the first opening and a second connection feature removably connected to the second half through the second opening. The first connection feature and the second connection feature can selectively engage with a snap-fit connection when the first half and the second half are in the closed position. The enclosure body is constructed via a first manufacturing process and wherein the first connection feature and the second connection feature are constructed via a second manufacturing process.

In some forms, a) the first manufacturing process is thermoforming and the second manufacturing process is injection molding; b) the first connection feature includes a first base and a male connector integrally formed with the first base; c) the second connection feature includes a second base and a female connector integrally formed with the second base; d) the first base and the second base are at least partially received within an inner volume of the enclosure body; and/or f) the male connector and the female connector are disposed at least partially outside of the inner volume.

In some forms, a) the first connection feature includes a first base and a male connector that can snap fit to the first base; b) the second connection feature includes a second base and a female connection feature that can snap fit to the second base; c) the first base and the second base are at least partially received within an inner volume of the enclosure body; d) the male connector and the female connector are disposed at least partially outside of the inner volume; and/or e) the first base and the second base are identical.

In certain forms, a) the first base includes a body with a central portion and a projection extending from the body proximate to the central portion; b) the projection includes an aperture; c) the first part includes an end having a wall and a groove formed against to the wall; and/or d) the wall can be received in the aperture when the male connector moves along the central portion to connect the first part to the first base.

In certain forms, a) the first base includes a central portion and a stop that extends from the body proximate to the central portion; b) the male connector includes an end having a wall and a prong extending from an inner surface of the wall; c) the first part is movable between a detached position where the prong is spaced apart from the stop and a connected position where the prong is in contact with the stop; and/or d) the prong is configured permit the first part to move along the central portion is a first direction between the detached position and connected position and limit the first part from moving along the central portion in a second direction opposite to the first direction between the connected position and the detached position.

In certain forms, a) the male connector includes a body, a projection, a retaining feature, and/or a prong; b) the body has a first end and a second end that is angled relative to the first end; c) the projection disposed proximate to the first end; d) retaining feature is disposed on an outer surface of the body proximate to the second end; e) the retaining feature includes a first wall protruding from the body, a second wall protruding from the body, and a groove formed between the first wall and the second wall; f) prong disposed on an inner surface of the body proximate to the second end; and/or g) the connection between the male connector and the female connector is configured to permit pivotable movement.

In certain forms, a) the female connector includes a body, a body opening, a retaining feature, and/or a prong; b) the body has a first end and a second end; c) the body opening extends through the body proximate to the first end; d) the retaining feature is disposed on an outer surface of the body proximate to the second end; e) the retaining feature includes a first wall protruding from the body, a second wall protruding from the body, and a groove formed between the first wall and the second wall; and/or f) the prong is disposed on an inner surface of the body proximate to the second end.

According to one aspect of various embodiments of the present disclosure there is provided an enclosure for selectively enclosing an electrical device. The enclosure includes an enclosure body, a first base, a male connector, a second base, and a female connector. The enclosure body includes a first half with a first opening and a second half with a second opening. The second half is movable relative to the first half between an opened position and a closed position. The first base is positioned at least partially through the first opening. The male connector is snap fit to the first base to secure the male connector and the first base to the first half. The second base is positioned at least partially through the second opening. The female connector is snap fit to the second base to secure the female connector and the second base to the second half. The male connector and the female connector are selectively engaged with a snap-fit connection when the first half and the second half are in the closed position. The first base and the second base are identical.

In some forms, the first body includes a) a body having a central portion; b) a projection extending from the body proximate to the central portion, wherein the projection includes an aperture; and/or c) a stop extending from the body proximate to the central portion.

In some forms, a) the male connector includes an end having a wall and a groove formed against an outer surface of the wall; b) a prong extends from an inner surface of the wall; c) the wall can be received in the aperture when the male connector moves along the central portion to connect the male connector to the first base; d) the male connector is movable between a detached position where the prong is spaced apart from the stop and a connected position where the prong is in contact with the stop; and/or e) the prong can permit the male connector to move along the central portion is a first direction between the detached position and connected position and limit the male connector from moving along the central portion in a second direction opposite to the first direction between the connected position and the detached position.

In some forms, a) the enclosure body is constructed via thermoforming; and/or b) the first connection feature and the second connection feature are constructed via injection molding.

According to one aspect of various examples of the present disclosure there is provided a method of constructing an enclosure for at least partially enclosing. The method includes manufacturing a first half of an enclosure body and a second half of the enclosure body using a first manufacturing process. The first half and the second half can form an enclosure volume. The method also includes manufacturing a male connector and a female connector using a second manufacturing process that is different than the first manufacturing process. The method further includes connecting the male connector to one of the first half and the second half and connecting the female connector to the other of the first half and the second half. The male connector can selectively engage with the female connector with a snap fit when the first half and the second half are in a closed position.

In some forms, a) the first manufacturing process is thermoforming and the second manufacturing process is injection molding; b) the male connector includes a first base and a male insert that can snap fit to the first base; c) the female connector includes a second base and a female insert that can snap fit to the second base; d) the first base and the second base are at least partially received within an inner volume of the enclosure body; e) the male connector and the female connector are disposed at least partially outside of the inner volume; and/or f) the first base and the second base are identical.

In some forms, a) connecting the male connector to the one of the first half and the second half includes positioning a first base through an opening in the one of the first half and the second half, and translating the male connector along the first base until a prong of the male connector contacts a stop of the first base; b) he prong is formed on an inner surface of both the first insert and the second insert and the stop is spaced apart from the projection; c) connecting the female connector to the other of the first half and the second half includes positioning a female insert at least partially through an opening in the other of the first half and the second half so that an insertion opening is exposed and can receive the male connector, and positioning a second base at least partially through the opening to connect to the other of the first half and the second half with a snap fit; d) the female connector and the second base are integrally formed; and/or e) the connection between the male connector and the female connector is configured to permit pivotable movement.

The disclosure herein should become evident to a person of ordinary skill in the art given the following enabling description and drawings. The drawings are for illustration purposes only and are not drawn to scale unless otherwise indicated. The drawings are not intended to limit the scope of the invention. The following enabling disclosure is directed to one of ordinary skill in the art and presupposes that those aspects within the ability of the ordinarily skilled artisan are understood and appreciated.

### BRIEF DESCRIPTION OF THE DRAWINGS

Various aspects and advantageous features of the present disclosure will become more apparent to those of ordinary skill when described in the detailed description of preferred embodiments and reference to the accompany drawing wherein:

FIG. 1 is a perspective view of an enclosure connected by an insert device.

FIG. 2 is a perspective view of a first half of the enclosure of FIG. 1 coupled to a male half of the insert device.

FIG. 3 is a perspective view of a second half of the enclosure of FIG. 1 coupled to a female half of the insert device.

FIG. 4 is a perspective view of the male half of the insert device.

FIG. 5 is a rear view of the male half of the insert device of FIG. 4.

FIG. 6 is a top view of the male half of the insert device of FIG. 4.

FIG. 7 is an exploded view of the male half of the insert device of FIG. 4.

FIG. 8 is a perspective view of a base of the male half of the insert device of FIG. 4.

FIG. 9 is a front perspective view of the base of FIG. 8.

FIG. 10 is a side view of the base of FIG. 8.

FIG. 11 is a perspective view of the female half of the insert device.

FIG. 12 is a front view of the female half of the insert device of FIG. 11.

FIG. 13 is an exploded view of the female half of the insert device of FIG. 11.

FIG. 14 is a rear perspective view of the female half of the insert device of FIG. 11 decoupled from a base.

FIG. 15 is a perspective view of an alternate example of the female half of the insert device.

FIG. 16 is a front view of the female insert device of FIG. 15.

FIG. 17 is a perspective view of the male half of the insert device of FIG. 4 received within the female half of the insert device of FIG. 11.

FIG. 18 is a side view of the male half of the insert device of FIG. 4 received within the female half of the insert device of FIG. 11.

FIG. 19 is a cross-sectional view of FIG. 17 viewed along section 19 —- 19 illustrating the male half of the insert device of FIG. 4 received within the female half of the insert device of FIG. 11.

FIG. 20 is a perspective view of a further alternate example of an insert device coupled to the enclosure.

FIG. 21 is a detail view of the insert device of FIG. 20.

FIG. 22 is a perspective view of a first portion of the insert device of FIG. 21.

FIG. 23 is a perspective view of a second portion of the insert device of FIG.

FIG. 24 is a perspective view of the insert device of FIG. 20 pivoted to an opened position.

### DETAILED DESCRIPTION

An enclosure 25 may be used to at least partially enclose an electrical device (e.g., an insulator bushing) to limit access to the electrical device by animals (e.g., birds, small mammals, etc.). The enclosure 25 may be constructed from an at least partially rigid material (e.g., plastic) using a thermoforming process.

In some forms, technicians may want the enclosure 25 to be repeatably opened and closed. This may permit a technician to selectively service the electrical device enclosed within the enclosure 25 without needed to break an existing enclosure 25 and replace it with a new enclosure 25.

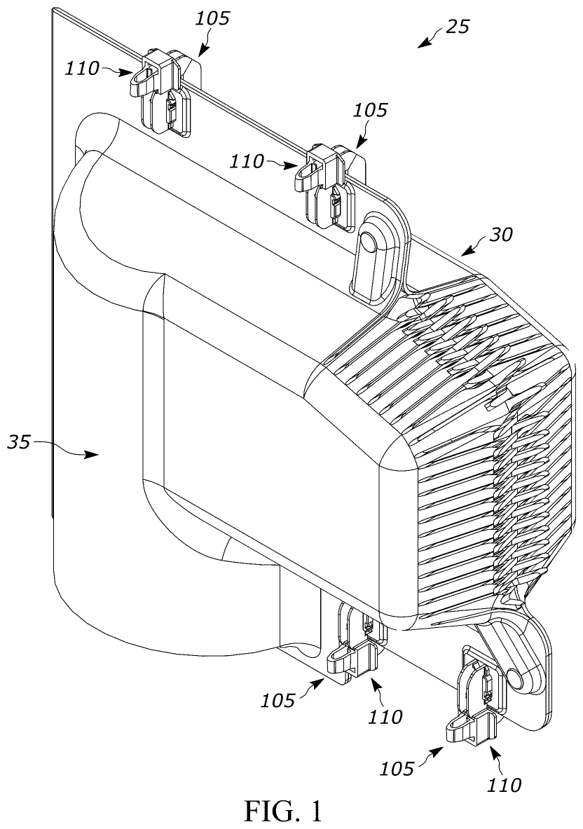

As shown in FIG. 1, the enclosure 25 may include a first half 30 and a second half 35 that are movable connected to one another. The first and second halves 30, 35 may be selectively secured in a closed position by one or more insert devices 100, which each include a male portion 105 and a female portion 110 that selectively receives the male portion 105. As described in more detail below, the male portion 105 and the female portion 110 may be selectively movable relative to one another (e.g., as the first and second halves 30, 35 move between an opened and closed position). As described in more detail below, the insert device 100 may be formed from a different manufacturing process (e.g., in injection molding) than the remainder of the enclosure 25.

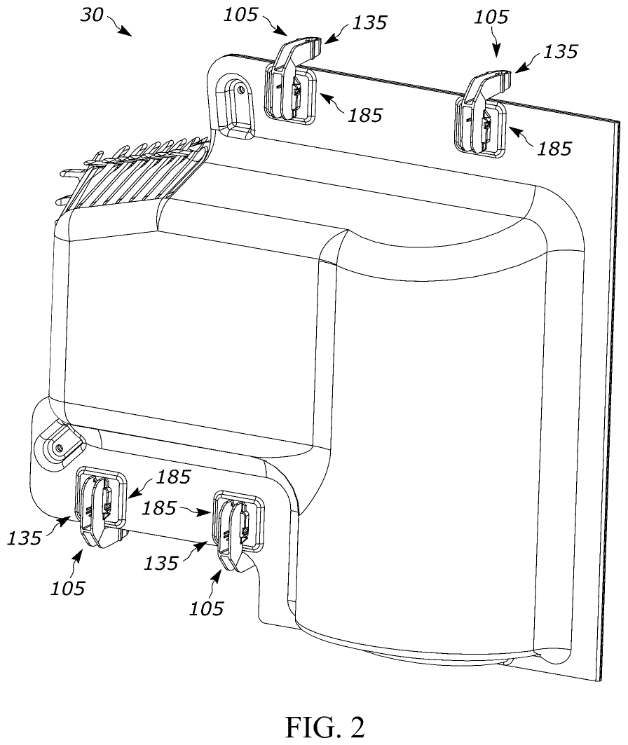

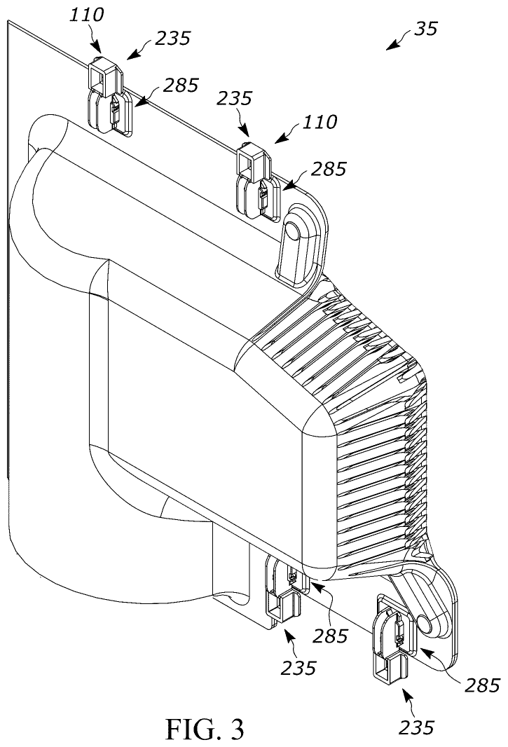

As shown in FIGS. 2 and 3, the first half 30 of the enclosure 25 may include the male portion 105 and the second half 35 of the enclosure 25 may include the female portion 110. The male portion 105 may be coupled to the first half 30 so that it moves together with the first half 30. The female portion 110 may be coupled to the first half 35 so that it moves together with the first half 35.

In some forms, the male portion 105 and/or the female portion 110 may be constructed from a different manufacturing process than the enclosure 25 (e.g., the first and second halves 30, 35). For example, the male 105 and/or female portions 110 may be formed via injection molding. As described in more detail below, injection molding the male and/or female portions 105, 110 may permit the formation of more complex geometries than can be achieved, which may be needed to create a snap fit connection. The male and female portions 105, 110 can then be connected to the respective half 30, 35 of the enclosure 25.

Some forms of the first half 30 may include one or more apertures, each formed proximate to an outer edge. The manufacturing process used to form the first half 30 may be capable of forming aperture that can receive another element.

In some forms, the aperture may include a substantially rectangular (e.g., square) opening. In other examples, the aperture may include another shape (e.g., circular, elliptical, triangular, etc.).

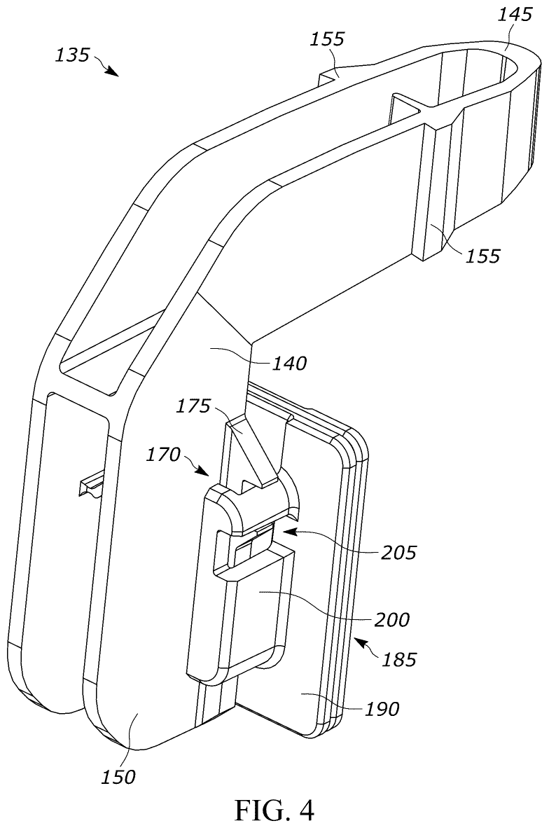

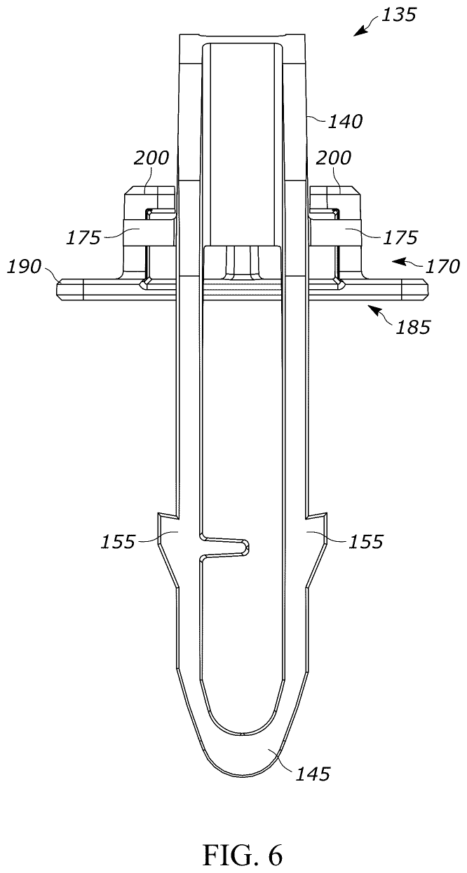

The male portion 105 may include a first part or insert 135. As illustrated in FIGS. 4 to 7, the first part 135 may be a male part, although in other examples, the first part 135 could have a different shape (e.g., a female part).

With continued reference to FIGS. 4 to 7, the first part 135 includes an elongated body 140 that extends between a first end 145 and a second end 150. The illustrated body 140 may be at least partially curved or angled so that the first end 145 and the second end 150 are substantially perpendicular to one another. However, other examples of the body 140 may have a different shape so that the first and second ends 145, 150 include a different angular spacing.

In some forms, the first end 145 may include an at least partially rounded shape (e.g., semi-circular). The first end 145 may be formed by a wall (e.g., a continuous wall). A space may be formed between opposing portions of the wall so that the first end 145 is substantially hollow between the opposing portions of the wall.

In certain forms, projections 155 may extend from the surface of the wall proximate to the first end 145. In the illustrated example, one projection 155 is formed on an outer surface of the wall on either side of the first end 145. The illustrated projections 155 may include substantially the same shape and be disposed substantially the same distance from the first end 145. In other examples, there may be any number of projections 155, and/or the projections 155 may have any shape and/or be disposed any distance from the first end 145.

In one form, each projection 155 may include an inclined surface that extends away from the wall. For example, the include surfaces may be sloped away from first end so that the width of each projection 155 is greater more distal to the first end 145. The projections 155 may serve as ramps and permit the first part 135 to move in one direction and limit movement in the other direction.

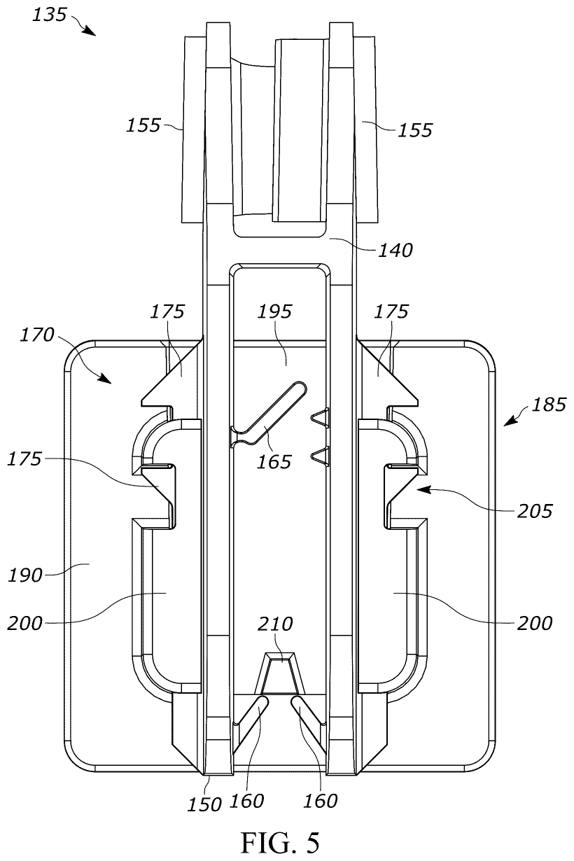

As shown in FIG. 5, the wall of the body 140 may extend away from the first end 145 and toward the second end 150. A space between the wall may be similarly formed proximate to the second end 150. In the illustrated example, the wall may not extend entirely to the second end 150 so that the cavity between the wall is accessible at the second end 150. In other examples, the wall may extend across the second end 150 similar to the first end 145.

In some forms, one or more prongs 160 may be formed within the space proximate to the second end 150. In the illustrated example, a pair of prongs 160 may be formed within the space where each prong 160 is approximately the same distance from the second end 150.

The prongs 160 may extend from the wall at the same angle, although each may extend at any angle. The illustrated prongs 160 may extend the same distance from the wall. The prongs 160 may be cantilever members that may be permitted to flex relative to the wall.

In certain forms, an additional prong 165 may extend from the wall in the central space. The illustrated additional prong 165 may be larger than the prongs 160 and may be disposed further from the second end 150. The additional prong 165 may also extend at a different angle than the prongs 160 (e.g., a shallower angle), although the additional prong 165 may extend at any angle.

In some forms, retaining features 170 may be formed on an outer surface of the wall. For example, the first part 135 may include a pair of retaining features 170 disposed on opposite faces of the outer surface of the wall. The illustrated retaining features 170 may be a substantially equal distance from the second end 150.

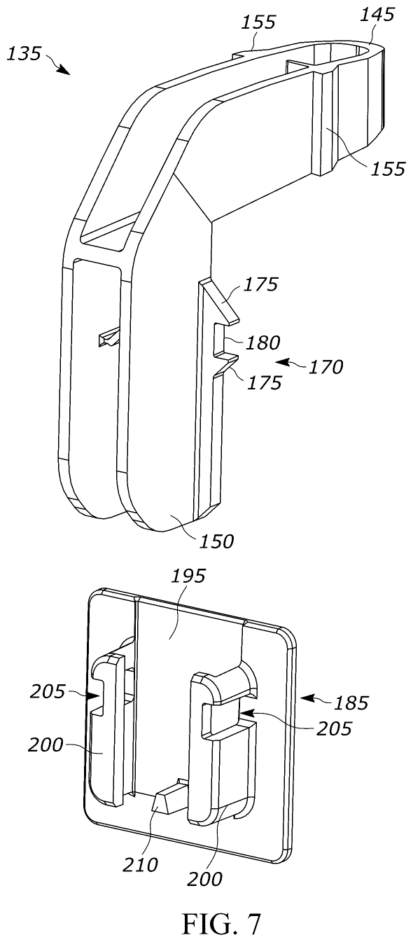

As shown in FIG. 7, certain forms of each retaining feature 170 may include a pair of sloped walls 175 and a groove 180 formed between the sloped walls 175. In the illustrated example, the sloped wall proximate to the second end 150 may be steeper than the sloped wall distal to the second end 150. The illustrated groove 180 may be angled with a substantially rectangular shape, although it may include any other shape (e.g., curved walls).

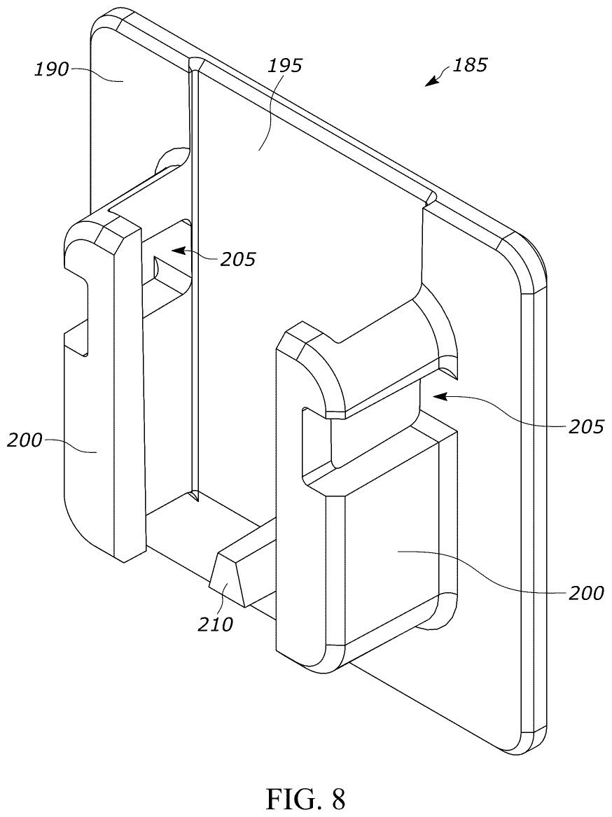

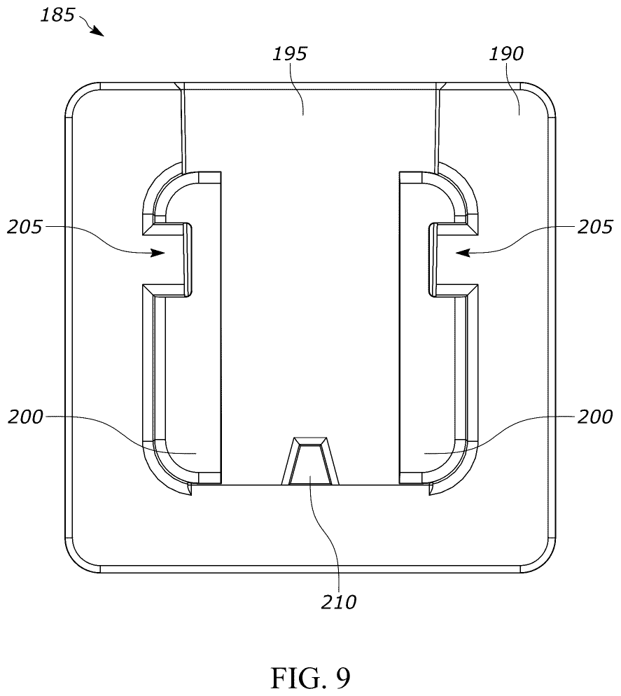

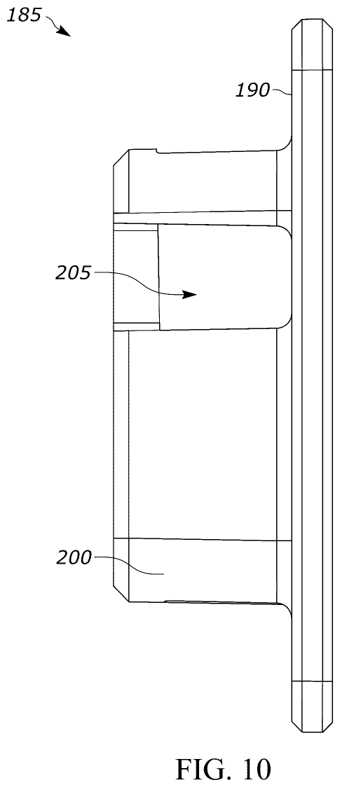

As shown in FIGS. 7 to 10, a first base 185 may include a body 190 with a substantially rectangular shape. The shape may be substantially the same as the shape of the aperture 130. In the illustrated example, the first base 185 may include a thickness around its perimeter that is similar to the shape of the boss 137.

In some forms, a central portion 195 of the body 190 may include a thickness that is less than the surrounding sections of the body 190. The reduced thickness of the central portion 195 may form a channel, which as described below, may facilitate the connection of the first part 135.

In some forms, a projection 200 may extend from the body 190 on either side of the central portion 195. For example, each projection 200 may be formed directly adjacent to the central portion 195. The illustrated projections 200 extend along a substantial length of the central portion 195, although other examples may include a different length.

In the illustrated example, each projection 200 may be formed as a cantilever member with a substantially L shape. Each projection 200 may be longer in a direction away from the surface of the body 190 than along the surface of the body 190. However, other examples of the projection 200 may include any shape.

In some forms, each projection 200 may include an opening 205 that extends along a surface of the projection substantially perpendicular to the body 190. The illustrated opening 205 may include an elongated shape (e.g., substantially rectangular), although the opening 205 may include any shape.

In some forms, a stop 210 may extend from the body 190. For example, the stop 210 may extend substantially perpendicular from the surface of the body 190 in substantially the same direction as the projections 200. The stop 210 may be formed at the end of the central portion 195 between (e.g., equally between) the projections 200.

The first base 185 may be inserted through an aperture in the body of the first half 30. The aperture may be formed proximate to an outer perimeter of the first half 30 during its manufacturing process. The first part 135 and the first base 185, which are formed separately, can then be connected to the first half 30. The first base 185 may be inserted so that the projections 200 are oriented outwardly and away from an inner cavity of the enclosure 25. The body 190 may be received within the boss so that the opposite surface of the first half 30 remains substantially flat.

In some forms, the first base 185 may be connected in this position by a snap-fit, a press fit, or a friction fit. Alternatively, or in addition, a fastener (e.g., a magnetic fastener, a mechanical fastener, an adhesive, etc.) may be used to connect the first base 185 to the first half 30. In still other examples, the first base 185 may be freely movable relative to the first half 30.

Once connected, the first part 135 may be connected to the first base 185. Specifically, the second end 150 may be positioned adjacent to the body 190 and translated along the central portion 195. The height of the retaining features 170 may be less than the height of the projections 200 so that the movement of the first part 135 is not substantially obstructed by the free ends of the projections 200. In some forms, the free ends of the projections 200 may limit translational movement in one direction (e.g., away from the surface of the body 190) but permit translational movement in another direction (e.g., a perpendicular direction along the surface of the body 190).

As the first part 135 moves along the central portion 195, the projections 200 come into contact with the respective proximate sloped walls 175. The slope of the proximate sloped walls 175 may assist each projection 200 to move around the respective sloped wall 175. After moving around the proximate sloped walls 175, each opening 205 may receive the respective sloped wall 175. Simultaneously, an end of each projection 200 (e.g., the end proximate to the opening 205) may be received within the groove 180. This connection (e.g., a snap-fit connection) may connect the first part 135 to the first base 185 on the first half 30 and limit movement (e.g., translation) of the first part 135 and the first base 185.

In some forms, the stop 210 may have a surface with a similar angle as the angle that the prongs 160 project from the wall. As the first part 135 moves along the central portion 195, the prongs 160 may come into contract with the stop 210. The resilience of the prongs 160 may permit the prongs 160 to move around the stop 210. Once past the stop 210, the prongs 160 may return to their original position. In this position, the prongs 160 may be in contact with the stop 210 and may limit translational movement of the first part 135 relative to the first base 185.

In other forms, the first part 135 and the first base 185 may be formed as an integral part. For example, the elongated body 140 may be integrally formed with the central portion 195. In that example, the retaining features 170 may be omitted. The first end 145 of the first part 135 may be sized and shaped to fit through an aperture in the first half 30 and the first base 185 connects to the first half 30 at least partially through the aperture (e.g., with a snap fit) as described above. In other examples, the first half 30 may include a slot, and the integrally formed first part 135 and first base 185 can be translated into the slot to connect to the first half 30.

Some forms of the second half 35 may include one or more apertures, each formed proximate to an outer edge. The manufacturing process used to form the second half 35 may be capable of forming aperture that can receive another element.

In some forms, the aperture may include a substantially rectangular (e.g., square) opening. In other examples, the aperture may include another shape (e.g., circular, elliptical, triangular, etc.).

In certain forms, the shape of the aperture may be the same on the first half 30 and on the second half 35. This may permit the male portion 105 and the female portion 110 to be connected to either half 30, 35.

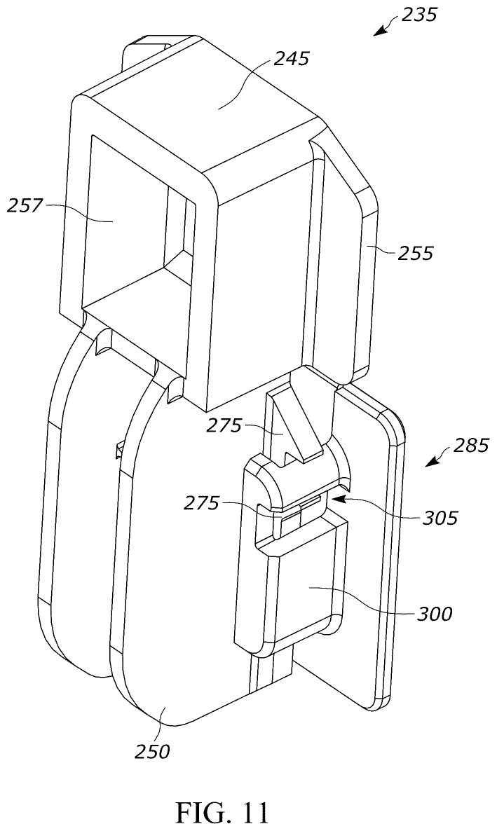

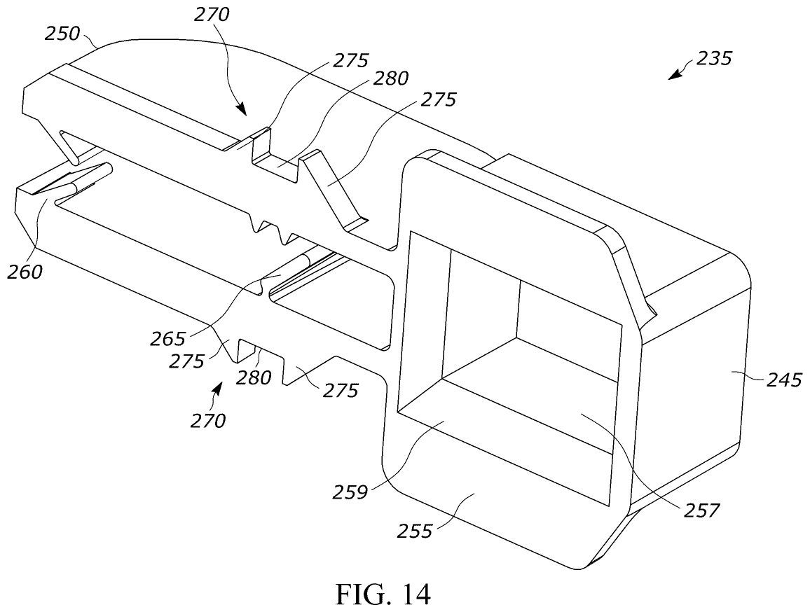

The female portion 110 may also include a second part or insert 235 that is connectable to the body 215. As illustrated in FIGS. 11 to 14, the second part 235 may be a female part, although in other examples, the second part 235 could have a different shape (e.g., a male part).

As shown in FIG. 11, the second part 235 includes an elongated body 240 that extends between a first end 245 and a second end 250. An axis may extend along the illustrated body 240 between the first end 245 and the second end 250. However, other examples of the body 240 may have a different shape so that the first and second ends 245, 250 include a different angular spacing.

In some forms, the first end 245 may include an at least partially rounded shape (e.g., rounded rectangular). The first end 245 may be formed by a wall (e.g., a continuous wall). A space may be formed between opposing portions of the wall so that the first end 245 is substantially hollow between the opposing portions of the wall.

In certain forms, projections 255 may extend from the surface of the wall proximate to the first end 245. In the illustrated example, one projection 255 is formed on an outer surface of the wall on either side of the first end 245. The illustrated projections 255 may include substantially the same shape and be disposed substantially the same distance from the first end 245. In other examples, there may be any number of projections 255, and/or the projections 255 may have any shape and/or be disposed any distance from the first end 245.

In the illustrated example, the projections 255 may be substantially elongated members and may extend from an edge of the wall. The thickness of the projections 255 may be less than a height of the wall.

In some forms, an aperture 257 may be formed between the wall proximate to the first end 245. The aperture 257 may have a substantially rectangularly shaped opening although other examples may have a different shape (e.g., circular, elliptical, etc.). The aperture 257 may also be wider at one end (e.g., proximate to the projections 255), although other examples may be wider at the opposite end or may be constant along the entire width.

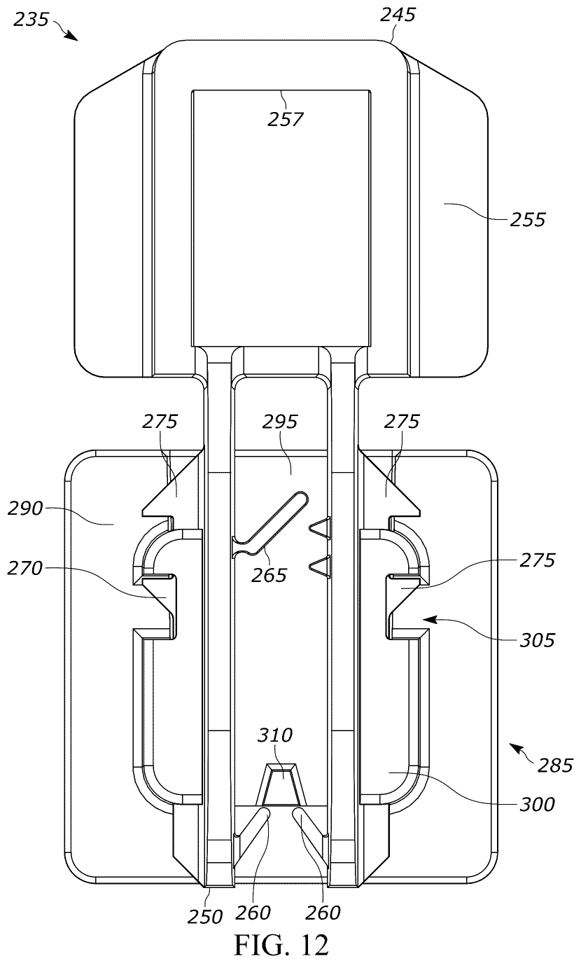

As shown in FIG. 12, the wall of the body 240 may extend away from the first end 245 and toward the second end 250. A space between the wall may be similarly formed proximate to the second end 250. In the illustrated example, the wall may not extend entirely to the second end 250 so that the cavity between the wall is accessible at the second end 250. In other examples, the wall may extend across the second end 250 similar to the first end 245.

In some forms, one or more prongs 260 may be formed within the space proximate to the second end 250. In the illustrated example, a pair of prongs 260 may be formed within the space where each prong 260 is approximately the same distance from the second end 250.

The prongs 260 may extend from the wall at the same angle, although each may extend at any angle. The illustrated prongs 260 may extend the same distance from the wall. The prongs 260 may be cantilever members that may be permitted to flex relative to the wall.

In certain forms, an additional prong 265 may extend from the wall in the central space. The illustrated additional prong 265 may be larger than the prongs 260 and may be disposed further from the second end 250. The additional prong 265 may also extend at a different angle than the prongs 260 (e.g., a shallower angle), although the additional prong 265 may extend at any angle.

In some forms, retaining features 270 may be formed on an outer surface of the wall. For example, the second part 235 may include a pair of retaining features 270 disposed on opposite faces of the outer surface of the wall. The illustrated retaining features 270 may be a substantially equal distance from the second end 250.

In certain forms, each retaining feature 270 may include a pair of sloped walls 275 and a groove 280 formed between the sloped walls 275. In the illustrated example, the sloped wall proximate to the second end 250 may be steeper than the sloped wall distal to the second end 250. The illustrated groove 280 may be angled with a substantially rectangular shape, although it may include any other shape (e.g., curved walls).

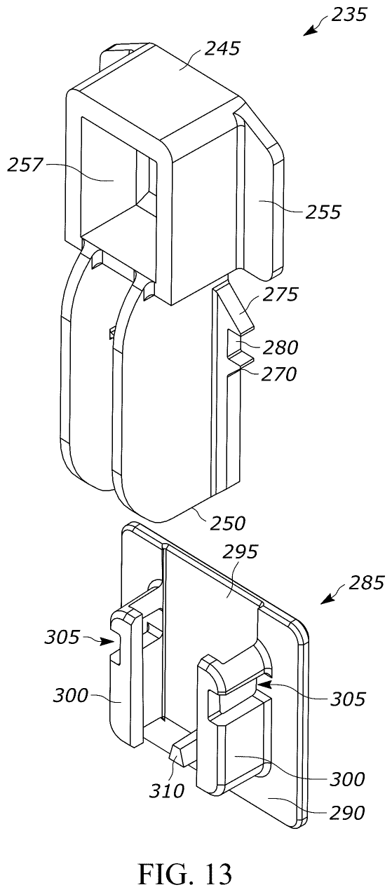

As shown in FIG. 13, a second base 285 may include a body 290 with a substantially rectangular shape. The shape may be substantially the same as the shape of the aperture on the second half 35. In the illustrated example, the second base 285 may include a thickness around its perimeter that is similar to the shape of a boss on the second half 35.

In some forms, the second base 285 may be substantially the same shape as the first base 185. The second base may similarly include a central portion 295 of the body 290, as well as projections 300 with openings 305, and a stop 310. The description of the related elements of the first base 185 apply to these elements.

The second base 285 may be inserted through the aperture in the second half 35. The second base 285 may be inserted so that the projections 300 are oriented outwardly and away from an interior of the enclosure 25. The body 290 may be received within a boss of the second half 35 so that the opposite surface (e.g., an inner surface) of the second half 35 remains substantially flat.

In some forms, the second base 285 may be connected in this position by a snap-fit, a press fit, or a friction fit. Alternatively, or in addition, a fastener (e.g., a magnetic fastener, a mechanical fastener, an adhesive, etc.) may be used to connect the second base 285 to the second half 35. In still other examples, the second base 285 may be freely movable relative to the second half 35.

Once connected, the second part 235 may be connected to the second base 285. Specifically, the second end 250 may be positioned adjacent to the body 290 and translated along the central portion 295. The height of the retaining features 270 may be less than the height of the projections 300 so that the movement of the second part 235 is not substantially obstructed by the free ends of the projections 300. In some forms, the free ends of the projections 300 may limit translational movement in one direction (e.g., away from the surface of the body 290) but permit translational movement in another direction (e.g., a perpendicular direction along the surface of the body 290).

As the second part moves 235 along the central portion 295, the projections 300 come into contact with the respective proximate sloped walls 275. The slope of the proximate sloped walls 275 may assist each projection 300 to move around the respective sloped wall 275. After moving around the proximate sloped walls 275, each opening 305 may receive the respective sloped wall 275. Simultaneously, an end of each projection 300 (e.g., the end proximate to the opening 305) may be received within the groove 280. This connection (e.g., a snap-fit connection) may connect the second part 235 to the second base 285 on the second half 35 and limit movement (e.g., translation) of the second part 235 and the second base 285.

In some forms, the stop 310 may have a surface with a similar angle as the angle that the prongs 260 project from the wall. As the second part 235 moves along the central portion 295, the prongs 260 may come into contract with the stop 310. The resilience of the prongs 260 may permit the prongs 260 to move around the stop 310. Once past the stop 310, the prongs 260 may return to their original position. In this position, the prongs 260 may be in contact with the stop 310 and may limit translational movement of the second part 235 relative to the second base 285.

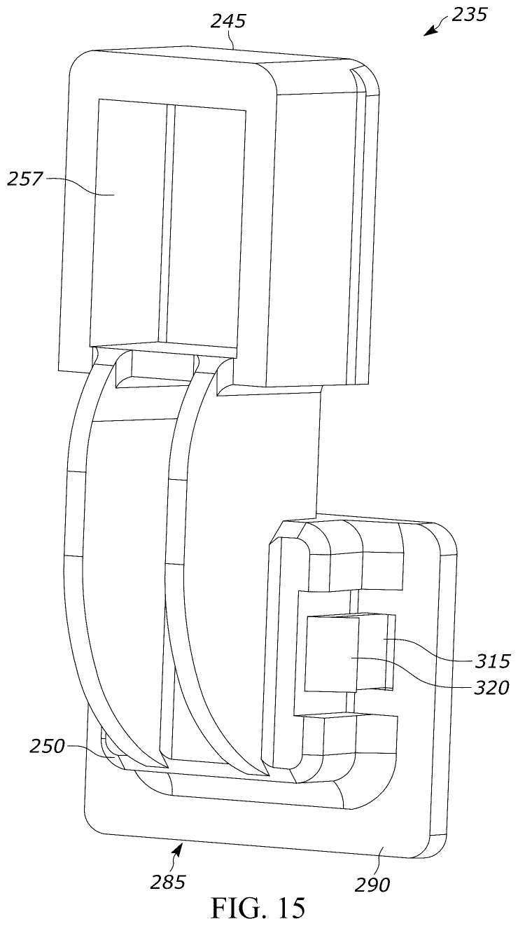

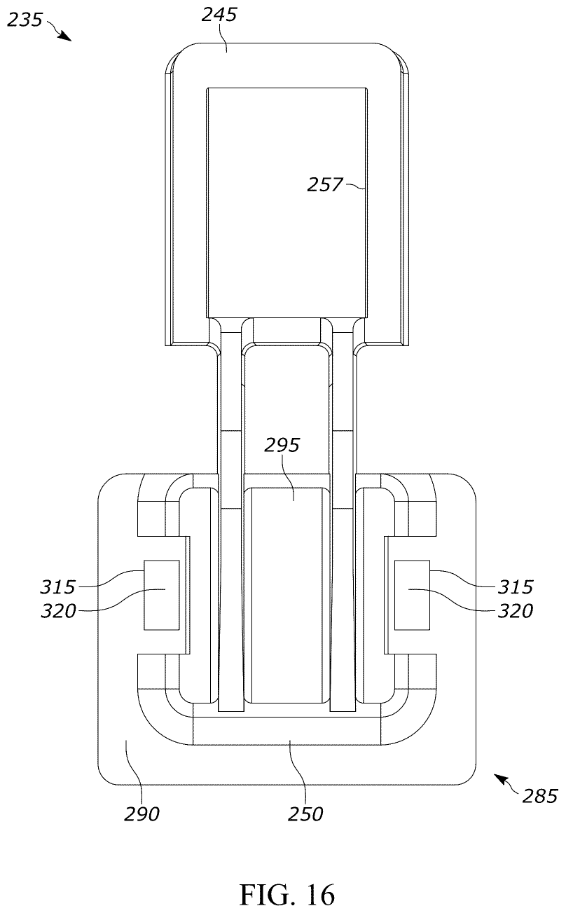

As shown in FIGS. 15 and 16, another example of the second part 235 and the second base 285 may be formed together as an integral part. For example, the elongated body 240 may be integrally formed with the central portion 295. In that example, the retaining features 270 may be omitted. The first end 245 of the second part 235 may be sized and shaped to fit through an aperture in the second half 35 and the second base 285 connects to the second half 35 at least partially through the aperture (e.g., with a snap fit) as described above. In other examples, the second half 35 may include a slot, and the integrally formed second part 235 and second base 285 can be translated into the slot to connect to the second half 35.

In some forms, the retaining features 270 on the second part 235 may be omitted since the second part 235 is not selectively coupled to the second base 285. The second base 285 may instead include a pair of tabs 315 disposed on either side of the body 240. Each tab 315 may be formed as a cantilever member that extends from the surface of the second base 285. A free end of each tab 315 may include an overhang 320, which may permit the second base 285 to couple to the second half 35. For example, the second part 235 may be maneuvered through the opening in the second half 35 so that it is outside of an inner cavity. The second base 285 can then be moved at least partially through the opening as described above. The tabs 315 may move through the opening until the overhangs 320 engage (e.g., with a snap fit) the second half 35 around the perimeter of the opening. The base 285 can be detached by manipulating (e.g., squeezing) the tabs 315 to permit them to decouple from the second half 35.

As described above, the first base 185 and the second base 285 may be similarly shaped so that either the first base 185 or the second base 285 can connect to either the first half 30 or the second half 35. Additionally, the second end 150 of the first part 135 may be similarly shaped to the second end 250 of the second part 235 so that either the first part 135 or the second part 235 can be connected with either the first base 185 or the second base 285. Furthermore, other parts (not shown) with other shapes may be connected to either the first base 185 or the second base 285 in place of either the first part 135 or the second part 235.

Returning to FIG. 1, the first and second halves 30, 35 may be connected together to form the enclosure 25. The first and second halves 30, 35 may be movable relative to one another between an opened and closed position (e.g., via a pivoting connection of a living hinge). The male and female parts 135, 235 may secure the first and second halves 30, 35 together to limit their relative motion (e.g., limit pivoting).

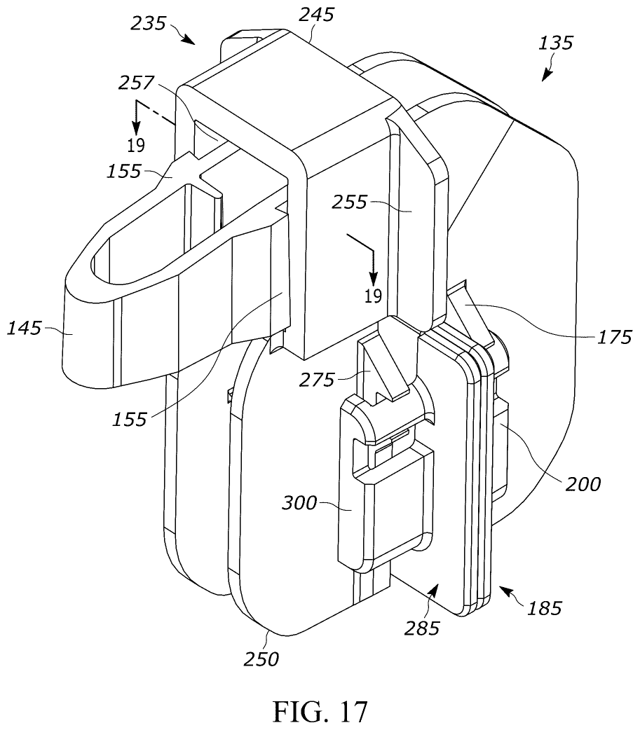

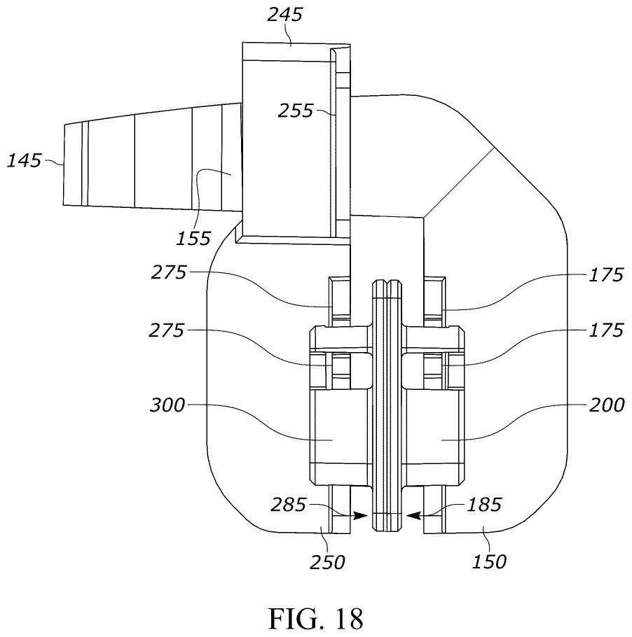

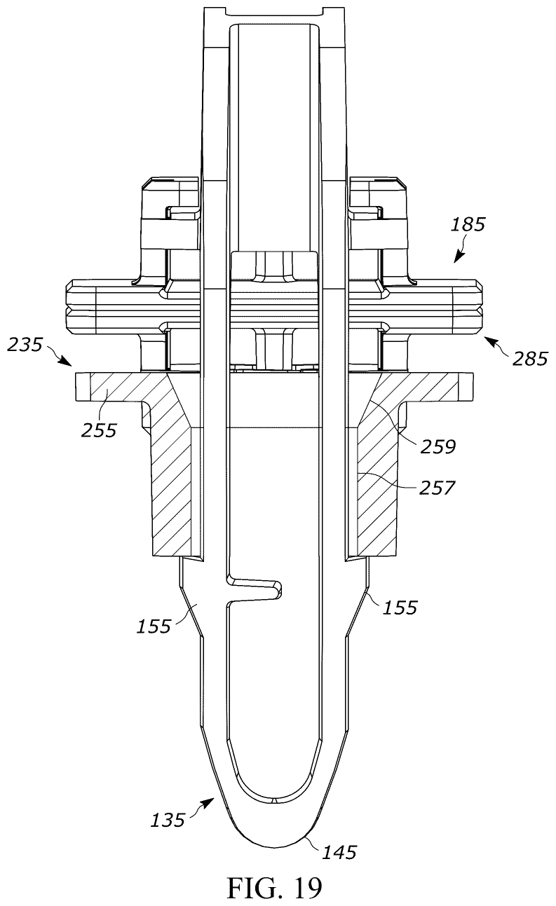

The first half 30 may move (e.g., be pivoted) so that the first part 135 is received within the second part 235 (see e.g., FIGS. 17 to 19). Specifically, the first end 145 of the first part 135 may be received through the aperture 257 of the second part 235.

In some forms, the width of the first end 145 of the male part 135 may be substantially similar to an inner width of the aperture 257 such that the first end 145 can pass through the aperture 257.

In certain forms, an insertion opening of the aperture 257 is wider than the remaining length of the aperture 257. The width of the insertion opening may be substantially equal to a width of the first end 145 including the projections 155. The insertion opening may also include ramped walls 259 that have a similar angle as the projections 155.

When the first end 145 is inserted into the aperture 257, the projections 155 may contact the ramped walls 259. As insertion continues, the ramped interface may assist in compressing the first end 145 so that the wider projections 155 can fit through the smaller width of the aperture 257. Once the projections 155 have cleared the aperture 257, the first end 145 may return to its initial position. The projections 155 may contact the second part 235 proximate to the aperture 257 to limit inadvertent removal.

In some forms, the first part 135 may engage the second part 235 in a snap-fit engagement so that the first part 135 may be removable from the aperture 257 of the second part 235. For example, a user may apply a compressive force at the first end 145 to decrease the width between opposing sides of the wall. This may permit the width of the first end 145 including the projections 155 to be less than the width of the aperture 257. The first half 30 can be moved (e.g., translated, pivoted, etc.) relative to the second half 35 to remove the first part 135 from the second part 235. This may permit a technician to move the enclosure 25 to an open position without breaking the enclosure 25. This also allows the same first and second parts 135, 235 to resecure the enclosure 25 in the closed position.

A user may also remove the first part 135 and/or the second part 235 from the respective halves 30, 35. For example, the user may flex the prongs 160, 260 to move around the stop 210, 310. Additionally, the user may apply a compressive force proximate to the second end 150, 250 to move the sloped walls 175, 275 out of engagement with the opening 205, 305. The respective first part 135 or second part 235 may be moved (e.g., translated) along the central portion 195, 295. This permits removal and/or replacement of a given part 135, 235 with a part of any other shape (e.g., a different type of connector). The substantially similar shape of the second end 150, 250 may permit this interchangeability. Other types of connectors that cannot be manufactured with the same process as the first and second halves 30, 35 can therefore be interchanged and used to selectively secure the first and second halves 30, 35 together in a closed position.

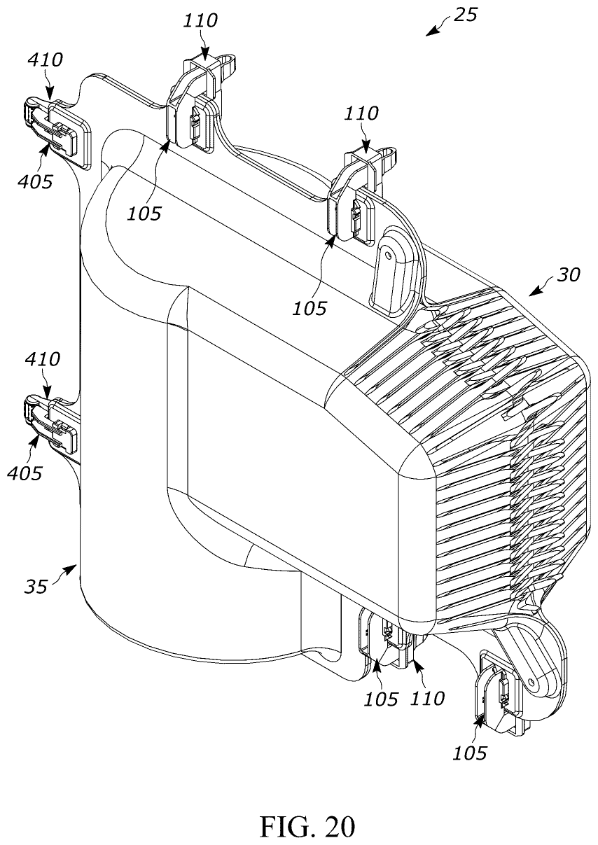

As shown in FIGS. 20 to 24, some forms of the halves 30, 35 may be pivotably movable relative to one another because of specific inserts (e.g., as opposed to a living hinge connecting the halves 30, 35 together). For example, the male and female portions 105, 110 on at least one edge of the first and second halves 30, 35 may be replaced with first and second pivoting inserts 405, 410 that allow the male and female portions 105, 110 to pivot relative to one another while remaining connected.

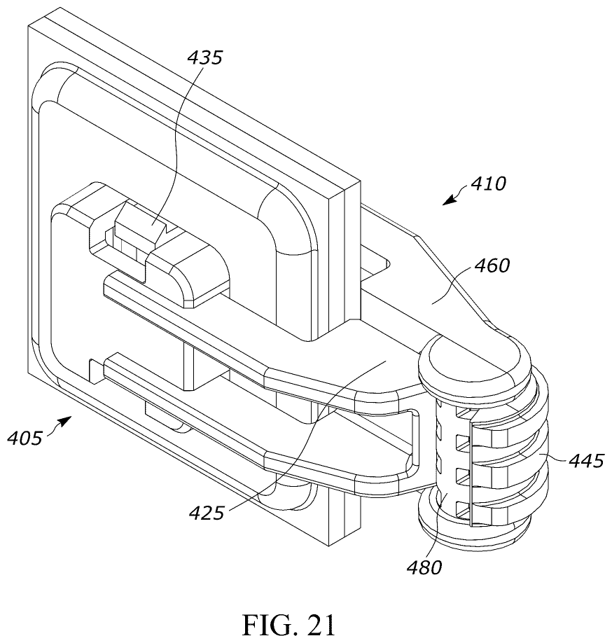

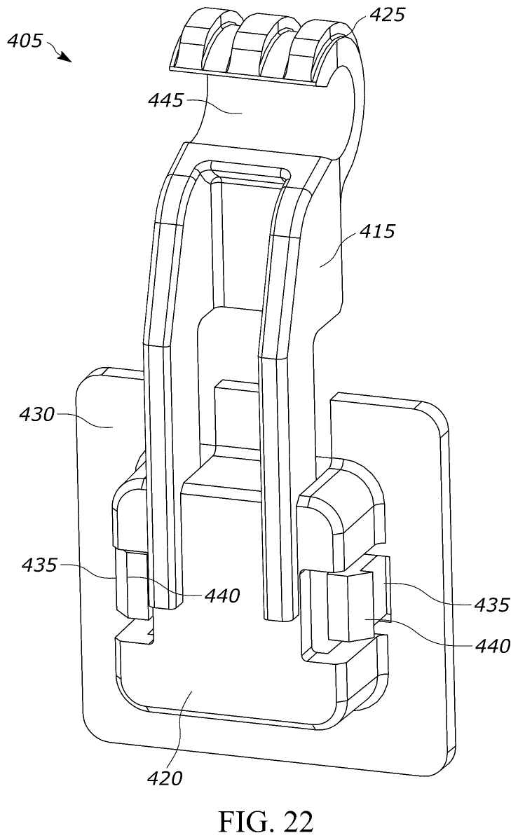

As shown in FIGS. 21 and 22, the first pivoting insert 405 may include an elongated body 415 that extends between a first end 420 and a second end 425. An axis may extend along the body 415 between the first and second ends 420, 425.

In some forms, the first end 420 may include a base 430 that is similar to the second base 285. Like in the second part 235, the base 430 may be integrally formed to the first end 420. The base 430 may include a pair of tabs 435, one disposed on either side of the base 430.

Each tab 435 may be formed as a cantilever member that extends from the surface of the base 430. A free end of each tab 435 may include an overhang 440, which may permit the base 430 to couple to either the first or second half 30, 35. For example, the first pivoting insert 405 may be maneuvered through the opening in the first or second half 30, 35 so that it is outside of an inner cavity. The base 430 can then be moved at least partially through the opening as described above. The tabs 435 may move through the opening until the overhangs 440 engage (e.g., with a snap fit) the first or second half 30, 35 around the perimeter of the opening. The base 430 can be detached by manipulating (e.g., squeezing) the tabs 435 to permit them to decouple from the first or second half 30, 35. Because the base 430 is substantially similar to the second base 285, the base 430 can generally connect to any portion of the first or second half 30, 35 where the second base 285 could connect.

However, in other examples, the first end 420 and the base 430 may be formed separately from one another and can be connected together (e.g., as described above with the retaining features 270 and the openings 305 in FIG. 13). Similar features may be included on the first end 420 and the base 430 to provide for a similar snap-fit connection.

With continued reference to FIG. 22, the second end 425 of the first pivoting insert 405 may include a hook or C-shaped portion 445. The hook portion 445 may be able to receive a curved (e.g., cylindrical) portion described below.

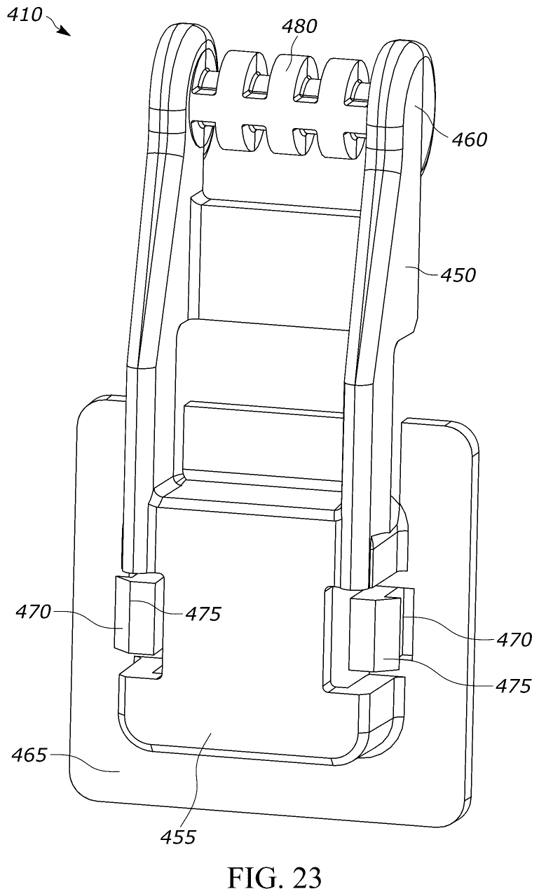

As shown in FIG. 23, the second pivoting insert 410 may include an elongated body 450 that extends between a first end 455 and a second end 460. An axis may extend along the body 450 between the first and second ends 455, 460.

In some forms, the first end 455 may include a base 465 that is similar to the base 430. For example, the base 465 may be substantially the same shape as the base 430. Additionally, the base 465 may include a pair of tabs 470 in substantially the same position as the pair of tabs 435 are located on the base 430. The tabs 470 may similarly include an overhang 475 that can permit the base 430 to couple to either the first or second half 30, 35 (e.g., the half that the first pivoting insert 405 is not connected to). The base 465 via the tabs 470 may connect to one of the first or second halves 30, 35 with a snap-fit in substantially the same way as the base 430 and the tabs 435 so that the first and second pivoting inserts 405, 410 can connect to either of the first and second halves 30, 35.

However, in other examples, the first end 455 and the base 465 may be formed separately from one another and can be connected together (e.g., as described above with the retaining features 270 and the openings 305 in FIG. 13). Similar features may be included on the first end 455 and the base 465 to provide for a similar snap-fit connection.

With continued reference to FIG. 23, the second end 460 of the second pivoting insert 410 may include a curved or cylindrical portion 480 that may correspond to the shape of the hook portion 445. Specifically, the cylindrical portion 480 may be received within the hook portion 445. The cylindrical portion 480 and the hook portion 445 may connect together with a snap fit.

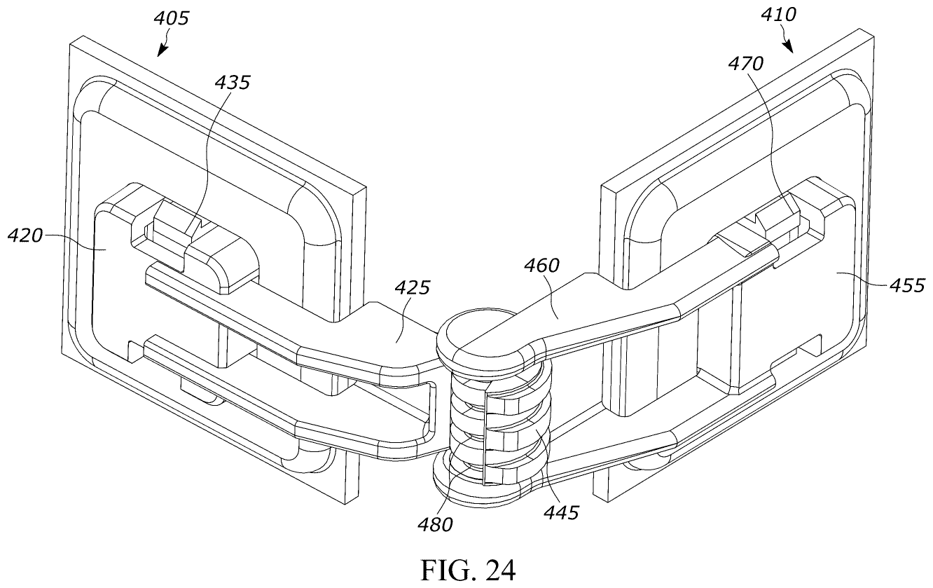

As shown in FIGS. 21 and 24, the connected first and second pivoting inserts 405, 410 allow for pivoting movement between a closed position (see e.g., FIG. 21) and an opened position (see e.g., FIG. 24). In the closed position, each first part 135 is received within the respective second part 235 with the snap fit to limit rotational movement of the first and second pivoting inserts 405, 410. In the opened position, each first part 135 is disconnected from the respective second part 235 to permit the pivoting movement of the first and second pivoting inserts 405, 410.

One of ordinary skill will appreciate that the exact dimensions and materials are not critical to the disclosure and all suitable variations should be deemed to be within the scope of the disclosure if deemed suitable for carrying out the objects of the disclosure.

One of ordinary skill in the art will also readily appreciate that it is well within the ability of the ordinarily skilled artisan to modify one or more of the constituent parts for carrying out the various embodiments of the disclosure. Once armed with the present specification, routine experimentation is all that is needed to determine adjustments and modifications that will carry out the present disclosure.

The above embodiments are for illustrative purposes and are not intended to limit the scope of the disclosure or the adaptation of the features described herein. Those skilled in the art will also appreciate that various adaptations and modifications of the above-described preferred embodiments can be configured without departing from the scope and spirit of the disclosure. Therefore, it is to be understood that, within the scope of the appended claims, the invention may be practiced other than as specifically described.

1. An enclosure for selectively enclosing an electrical device, the enclosure comprising:
an enclosure body including a first half with a first opening and a second half with a second opening, the second half being movable relative to the first half between an opened position and a closed position;
a first connection feature removably connected to the first half through the first opening; and
a second connection feature removably connected to the second half through the second opening;
wherein the first connection feature and the second connection feature selectively engage with a snap-fit connection when the first half and the second half are in the closed position; and
wherein the enclosure body is constructed via a first manufacturing process and wherein the first connection feature and the second connection feature are constructed via a second manufacturing process.

2. The enclosure of claim 1, wherein the first manufacturing process is thermoforming and the second manufacturing process is injection molding.

3. The enclosure of claim 1, wherein:
the first connection feature includes,
a first base,
a male connector configured to snap fit to the first base; and
the second connection feature includes,
a second base,
a female connector configured to snap fit to the second base;
wherein the first base and the second base are at least partially received within an inner volume of the enclosure body; and
wherein the male connector and the female connector are disposed at least partially outside of the inner volume.

4. The enclosure of claim 3, wherein the first base and the second base are identical.

5. The enclosure of claim 3, wherein:
the first base includes:
a body having a central portion,
a projection extending from the body proximate to the central portion, wherein the projection includes an aperture; and
the male connector includes an end having a wall and a groove formed against to the wall;
wherein the wall is configured to be received in the aperture when the male connector moves along the central portion to connect the male connector to the first base.

6. The enclosure of claim 3, wherein:
the first base includes:
a body having a central portion,
a stop extending from the body proximate to the central portion; and
the male connector includes an end having a wall and a prong extending from an inner surface of the wall;
wherein the male connector is movable between a detached position where the prong is spaced apart from the stop and a connected position where the prong is in contact with the stop; and
wherein the prong is configured permit the male connector to move along the central portion is a first direction between the detached position and connected position and limit the male connector from moving along the central portion in a second direction opposite to the first direction between the connected position and the detached position.

7. The enclosure of claim 3, wherein the male connector includes:
a body that has a first end and a second end that is angled relative to the first end;
a projection disposed proximate to the first end;
a retaining feature disposed on an outer surface of the body proximate to the second end, the retaining feature includes a first wall protruding from the body, a second wall protruding from the body, and a groove formed between the first wall and the second wall; and
a prong disposed on an inner surface of the body proximate to the second end.

8. The enclosure of claim 3, wherein the female connector includes:
a body that has a first end and a second end;
a body opening extending through the body proximate to the first end;
a retaining feature disposed on an outer surface of the body proximate to the second end, the retaining feature includes a first wall protruding from the body, a second wall protruding from the body, and a groove formed between the first wall and the second wall; and
a prong disposed on an inner surface of the body proximate to the second end.

9. The enclosure of claim 1, wherein:
the first connection feature includes,
a first base,
a male connector integrally formed with the first base; and
the second connection feature includes,
a second base,
a female connector integrally formed with the second base;
wherein the first base and the second base are at least partially received within an inner volume of the enclosure body; and
wherein the male connector and the female connector are disposed at least partially outside of the inner volume.

10. The enclosure of claim 1, wherein the first connection feature and the second connection feature are pivotably connected.

11. A method of constructing an enclosure for at least partially enclosing, the method comprising:
manufacturing a first half of an enclosure body and a second half of the enclosure body using a first manufacturing process, wherein the first half and the second half are configured to form an enclosure volume;
manufacturing a male connector and a female connector using a second manufacturing process that is different than the first manufacturing process;
connecting the male connector to one of the first half and the second half;
connecting the female connector to the other of the first half and the second half;
wherein the male connector is configured to selectively engage with the female connector with a snap fit when the first half and the second half are in a closed position.

12. The method of claim 11, wherein the first manufacturing process is thermoforming and the second manufacturing process is injection molding.

13. The method of claim 11, wherein connecting the male connector to the one of the first half and the second half includes positioning a first base through an opening in the one of the first half and the second half, and translating the male connector along the first base until a prong of the male connector contacts a stop of the first base, wherein the prong is formed on an inner surface of both the first insert and the second insert and the stop is spaced apart from the prong.

14. The method of claim 11, wherein:
the male connector includes,
a first base,
a male insert configured to snap fit to the first base; and
the female connector includes,
a second base,
a female insert configured to snap fit to the second base;
wherein the first base and the second base are at least partially received within an inner volume of the enclosure body; and
wherein the male connector and the female connector are disposed at least partially outside of the inner volume.

15. The method of claim 14, wherein the first base and the second base are identical.

16. The method of claim 11, wherein connecting the female connector to the other of the first half and the second half includes positioning a female insert at least partially through an opening in the other of the first half and the second half so that an insertion opening is exposed and configured to receive the male connector, and positioning a second base at least partially through the opening to connect to the other of the first half and the second half with a snap fit, and wherein the female connector and the second base are integrally formed.

17. The method of claim 11, wherein the connection between the male connector and the female connector is configured to permit pivotable movement.

18.-23. (canceled)

24. An enclosure for selectively enclosing an electrical device, the enclosure comprising:
an enclosure body including a first half with a first opening and a second half with a second opening, the second half being movable relative to the first half between an opened position and a closed position;
a first base positioned at least partially through the first opening;
a male connector snap fit to the first base to secure the male connector and the first base to the first half;
a second base positioned at least partially through the second opening; and
a female connector snap fit to the second base to secure the female connector and the second base to the second half;
wherein the male connector and the female connector selectively engage with a snap-fit connection when the first half and the second half are in the closed position; and
wherein the first base and the second base are identical.

25. The enclosure of claim 24, wherein
the first base includes:
a body having a central portion,
a projection extending from the body proximate to the central portion, wherein the projection includes an aperture, and
a stop extending from the body proximate to the central portion; and
the male connector includes an end having a wall and a groove formed against an outer surface of the wall, wherein a prong extends from an inner surface of the wall;
wherein the wall is configured to be received in the aperture when the male connector moves along the central portion to connect the male connector to the first base;
wherein the male connector is movable between a detached position where the prong is spaced apart from the stop and a connected position where the prong is in contact with the stop; and
wherein the prong is configured permit the male connector to move along the central portion is a first direction between the detached position and connected position and limit the male connector from moving along the central portion in a second direction opposite to the first direction between the connected position and the detached position.

26. The enclosure of claim 24, wherein the enclosure body is constructed via thermoforming and wherein the first connection feature and the second connection feature are constructed via injection molding.
